(19) United States
(12) Patent Application Publication
(10) Pub. No.: US 2014/0131912 A1
(43) Pub. Date: May 15, 2014

(54) SUPPRESSION OF DEWETTING OF POLYMER FILMS VIA INEXPENSIVE SOFT LITHOGRAPY

(71) Applicants: Alamgir Karim, Akron, OH (US); Diya Bandyopadhyay, Akron, OH (US)

(72) Inventors: Alamgir Karim, Akron, OH (US); Diya Bandyopadhyay, Akron, OH (US)

(73) Assignee: THE UNIVERSITY OF AKRON, Akron, OH (US)

(21) Appl. No.: 14/115,256

(22) PCT Filed: May 4, 2012
(86) PCT No.: PCT/US2012/036542

§ 371 Date: Jan. 30, 2014

Related U.S. Application Data
(60) Provisional application No. 61/482,487, filed on May 4, 2011.

(51) Int. Cl. G03F 7/00

(52) U.S. Cl. CPC G03F 7/00
USPC 264/134

(57) ABSTRACT

A method for producing a patterned polymer film on a substrate includes the steps of coating a substrate with a polymer film; placing a patterned mask onto the surface of the polymer film, the patterned mask having at least one pattern section of dimensions less than the capillary wavelength of the polymer film; annealing the polymer film by either solvent annealing or temperature-based annealing, which involves raising the temperature of the polymer film above its glass transition temperature, the step of annealing causing the polymer film to conform to the dimensions of the at least one pattern section of dimensions less than the capillary wavelength of the polymer film, thereby forming a patterned polymer film; and removing the patterned mask from the patterned polymer film.

### FIELD OF THE INVENTION

The present invention relates to substrates coated with patterned polymer films and to methods of forming and stabilizing the patterned polymer films against dewetting.

### BACKGROUND OF THE INVENTION

Polymers have many practical applications due to their easy processability, low cost, durability, and superior physical and chemical properties. Most advanced applications involving polymers such as organic photovoltaic solar cells, biomedical scaffolds, nanolithographic masks, and electronic circuit boards, require polymers to be in the form of patterned films coated on solid substrates.

However, the primary challenge in preparing such films is to uniformly spread and stabilize the film on the underlying solid substrate. In most practical applications, a smooth, stable, and defect free coating is desired and a persistent concern with such systems is their stability against dewetting. Owing to confinement effects in thin film systems, simultaneous interplay between short-range and long-range forces at the polymer-substrate interface can become increasingly predominant. These effects render thin films unstable or metastable, subject to unfavorable polymer-substrate interactions.

Polymer thin films generated by various techniques, such as spin coating and flow coating, relax from a metastable state towards a state of thermodynamic equilibrium, when annealed above their glass transition temperature or swollen by solvent vapors. This leads to a destabilization process ultimately resulting in film rupture and dewetting. In order to better understand the destabilization process, investigations regarding the actual mechanism and dynamics of dewetting have received much attention. In general, there is a need in the art to control instabilities more consistently and thus process robust and stable polymer thin films on various substrates.

Existing studies on stabilization of polymer thin films on solid substrates deal with substrate modifications, for example, the use of toxic and hazardous chemicals such as hydrofluoric acid (HF) for etching the film-destabilizing native oxide layer (typically-1-2 nm). Other strategies involve the modification of polymer chains in order to enhance polymer-substrate attractive interactions and thus film wetting. However, surface or polymer modifications in many cases are undesirable due to possible compromises in film functional characteristics and ultimate product properties. Said modifications are also costly and time-consuming

Yet another novel and relatively new stabilization method involves the addition of nanoparticles to a polymer film. The nanoparticles are shown to segregate to the film substrate interface and modify the polymer-substrate interaction. This nanoparticle surface enrichment layer enhances film stability by pinning the growing contact lines of dewetting holes that form in the film. However, due to the potential toxicity as well as high costs of nanoparticles, this route may not always be the most preferred one.

Given their vital significance in myriad potential applications such as biodegradable implants and scaffolds, light-emitting diodes, high-density data storage devices, nanolithographic masks, and photovoltaics, it is necessary to develop viable and inexpensive routes to control polymer film instabilities. The motivation behind the invention is to be able to couple polymer film stabilization against dewetting and simultaneously pattern the films in an inexpensive fashion for various high-end applications. Traditional techniques for patterning polymer films such as Nano-Imprint Lithography (NIL) and Reactive Ion Etching (RIE) involve very high costs, and require extremely clean laboratory conditions (clean-room conditions) and a high level of skill. The mask template used in these techniques is also expensive due to the use of cost-intensive photolithographic methods to create the templates in the first place. These limitations prohibit the mass-scale production capabilities of patterned polymer films as well as the reproducibility of the technique.

In a typical NIL technique, a silicon dioxide and silicon or ceramic mold is used. Electron beam lithography or RIE is used to generate the desired pattern on the mold. This is then imprinted onto a polymer resist, at a temperature above the glass transition temperature, Tg, of the polymer and at pressures typically between 500-2000 psi. Imprinting is carried out under vacuum and, once the resist is molded in the desired pattern shape, the mold is removed and RIE is carried out in order to remove any residual resist material in the compressed areas. Such a process is generally provided in Stephen Y. Chou, Peter R. Krauss, and Preston J. Renstrom, J. Vac. Sci. Technol. B. 14(6), 1996, 4129-4133.

Traditional methods of suppressing dewetting in polymer films involve the use of toxic chemicals, and/or chemical modifications of the polymer, and/or addition of nanoparticles to the polymer in order to modify substrate-polymer interactions, thereby increasing cost and hazard associated with the process.

Conventional lithographic techniques such as NIL and RIE have been used for patterning polymer films. However, these methods involve a large number of steps, require large equipment and clean-room costs, and are skill-intensive.

Thus, a need in the art exists for an inexpensive and time-efficient method of stabilizing polymer films on substrates against dewetting that can also include patterning the polymer film. The current invention eliminates the aforementioned issues by developing an inexpensive, clean and risk-free soft lithographic technique that can stabilize the polymer film without any system or substrate modification and can simultaneously generate patterns, rendering the films useful for a host of technological applications such as biomedical scaffolds, nano-electronics, and organic photovoltaic solar cells. According to the present invention, large areas of polymer films can be stabilized and patterned with very good long range ordering, without involving any expensive and sophisticated equipment, special environmental conditions and tedious experimental steps. This invention eliminates the use of controlled external pressure, clean-room conditions, expensive photolithographic masks, and thus reduces the cost and number of steps involved.

### SUMMARY OF THE INVENTION

In one or more embodiments the present invention provides a method for producing a patterned polymer film on a substrate, the method comprising the steps of: coating a substrate with a polymer film; placing a patterned mask onto the surface of the polymer film, the patterned mask having at least one pattern section of dimensions less than the capillary wavelength of the polymer film; annealing the polymer film by a step selected from solvent annealing and temperature-based annealing, which involves raising the temperature of the polymer film above its glass transition temperature, said step of annealing causing the polymer film to conform to the dimensions of the at least one pattern section of dimensions less than the capillary wavelength of the polymer film, thereby forming a patterned polymer film; and removing the patterned mask from the patterned polymer film.

In one or more embodiments the present invention provides a method as in paragraph [0012] further comprising the step of creating the patterned mask from a curable elastomer.

In one or more embodiments the present invention provides a method as in either paragraph [0012] or [0013] wherein the patterned polymer film is stabilized against dewetting.

In one or more embodiments the present invention provides a method as in any of paragraphs [0012] through [0014] wherein the step of annealing is a solvent annealing step and the method further comprises driving off the solvent after said step of annealing.

In one or more embodiments the present invention provides a method as in any of paragraphs [0012] through [0015] wherein the step of annealing is a temperature-based annealing step and the method further comprises quenching the polymer film after said step of annealing by reducing the temperature below the glass transition temperature.

In one or more embodiments the present invention provides a method as in any of paragraphs [0012] through [0016] wherein the patterned mask has at least one pattern section of dimensions greater than the capillary wavelength of the polymer film.

Yet another embodiment of the present invention provides a method for producing a patterned polymer film on a substrate, the method comprising the steps of coating a substrate with a polymer film; advancing said substrate below a patterned object such that the polymer film contacts the patterned object, the patterned object having at least one pattern section of dimensions less than the capillary wavelength of the polymer film; while the polymer film is in contact with the patterned object, annealing the polymer film by a step selected from solvent annealing and temperature-based annealing, said step of annealing causing the polymer film to conform to the dimensions of the at least one pattern section of dimensions less than the capillary wavelength of the polymer film, thereby forming a patterned polymer film; and advancing the patterned polymer film such that the patterned object no longer contacts the patterned polymer film.

In one or more embodiments the present invention provides a method as in paragraph [0018] wherein the patterned object is rotating.

In one or more embodiments the present invention provides a method as in either paragraph [0018] or [0019] wherein the patterned object is a patterned roller wheel.

In one or more embodiments the present invention provides a method as in any of paragraphs [0018] through [0020] wherein the step of annealing is a temperature-based annealing step and the method further comprises quenching the polymer film after said step of annealing by reducing the temperature below the glass transition temperature.

In one or more embodiments the present invention provides a method as in any of paragraphs [0018] through [0021] wherein the step of annealing is a solvent annealing step and the method further comprises driving off the solvent after said step of annealing.

In one or more embodiments the present invention provides a method as in any of paragraphs [0018] through [0022] wherein the rate of advancement allows the polymer film to fully anneal while in contact with the patterned object.

In one or more embodiments the present invention provides a method as in any of paragraphs [0018] through [0023] wherein the patterned object has at least one pattern section of dimensions greater than the capillary wavelength of the polymer film.

### BRIEF DESCRIPTION OF THE DRAWINGS

Advantages of the present invention will become better understood with regard to the following description, appended claims, and accompanying drawings wherein:

FIG. 1 is a schematic cross-sectional view of a curable elastomer casted onto a master pattern as a step toward creating an elastomeric mask;

FIG. 2 is a schematic cross-sectional view of the elastomer mask of FIG. 1, after it has been peeled off of the master pattern;

FIG. 3 is a schematic cross-sectional view of the elastomer mask placed on a polymer film that has been casted on a substrate;

FIG. 4 is a schematic cross-sectional view of the polymer film filling the elastomer mask after the polymer film has been annealed, though in certain sections the mask is shaped to permit dewetting of the polymer film, such that the polymer film does not fill those sections;

FIG. 5 is a schematic cross-sectional view of the patterned polymer film and substrate after the polymer film has been annealed and the elastomer mask has been removed; and

FIG. 6 is a schematic cross-sectional view of the present invention in an embodiment representing industrialization or an assembly line format.

### DETAILED DESCRIPTION OF ILLUSTRATIVE EMBODIMENTS

The present invention relates to a method of producing a stable, patterned polymer film secured to a substrate without suffering from dewetting. In this method, a uniform polymer film is provided on a surface of a solid substrate, and is then confined by a pre-patterned elastomeric mask. This confinement can be carried out without any applied pressure and under ambient laboratory conditions. The film, confined by the mask, is annealed either through solvent annealing or by raising the film to a temperature above the glass transition temperature, Tg, of the polymer, causing it to fill the patterned sections of the mask. In the case of solvent annealing, the solvent is subsequently driven off, and, in the case of temperature-based annealing, the polymer film is subsequently quenched at a temperature below Tg, after which the mask is removed to yield a high-fidelity pattern transfer accompanied by complete stabilization of the polymer film.

The method for stabilizing and patterning polymer films via inexpensive soft lithography will now be described in greater detail. It should be noted that the specific materials such as elastomers, polymers, solvents, and substrates, and the specific process conditions such as coating processes, curing temperatures and duration and annealing temperatures and duration disclosed in the following disclosures are given only as examples within the scope of the invention, and this invention should not be limited to these materials or process conditions as such.

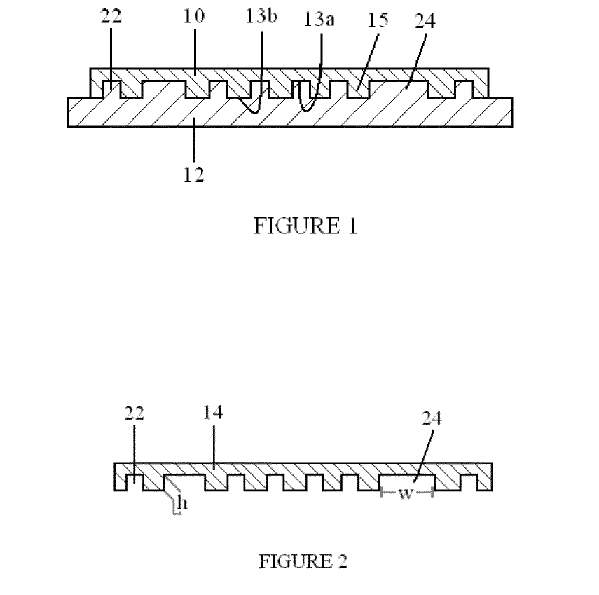

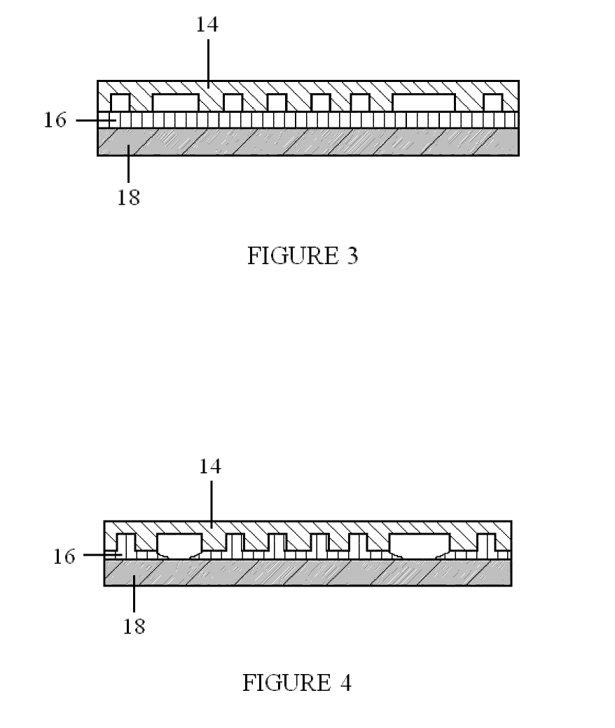

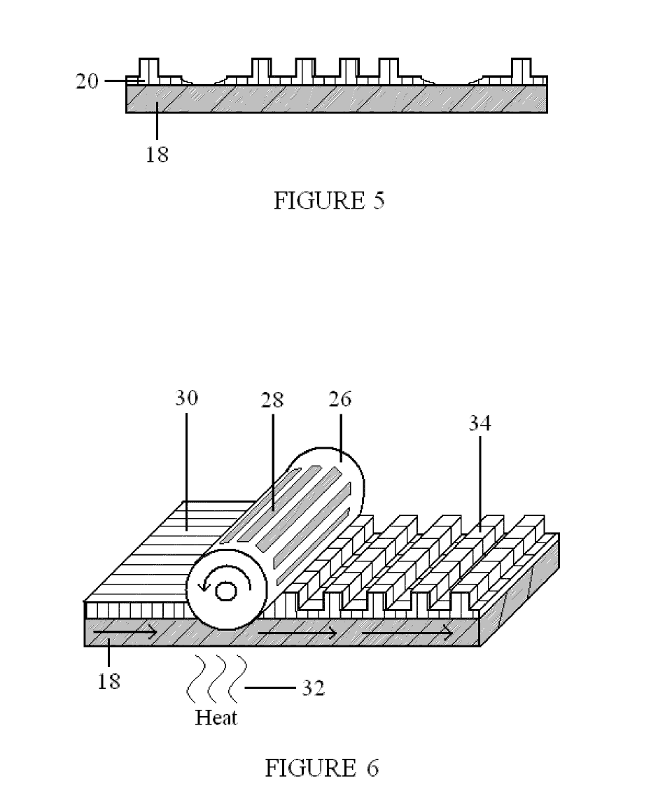

To carry out the process of this invention and create stable patterned polymer films on a substrate, an elastomeric mask is prepared in one step of the process. With reference to FIG. 1, an elastomeric mask is made by casting an curable elastomer 10 onto a master pattern 12 having multiple valleys 13a and peaks 13b defined by raised walls 15, the walls, peaks and valleys defining the desired pattern that is to be transferred to the elastomeric mask. The curable elastomer 10 conforms to the master pattern and is cured to set the pattern into the elastomer and thus create a cured elastomeric mask 14. As seen in FIG. 2, the cured elastomeric mask 14 is peeled off of the master pattern 12. With reference to FIG. 3, this mask 14 is used in subsequent steps to confine a polymer film 16 coated on a substrate 18. With the mask 14 in place on the polymer film 16, the polymer film 16 is annealed either through solvent annealing or by raising the polymer film 16 to a temperature above the glass transition temperature, Tg, of the polymer, causing it to fill the pattern of the mask 14, as seen in FIG. 4. In the case of solvent annealing, the solvent is subsequently driven off, and, in the case of temperature-based annealing, the polymer film 16 is subsequently quenched to a temperature below its Tg, and the mask 14 is peeled off, as seen in FIG. 5, leaving behind a patterned polymer film 20 that retains the desired pattern. This general process will be described more fully below. FIG. 6 shows an embodiment where the present invention is in industrialized or assembly line format.

Herein a digital versatile disc (DVD) is employed as the master pattern in a specific example, but the substrate may be widely chosen. As known, DVDs include a long spiral track having microscopic bumps, and this track provides the pattern that is imparted to the curable elastomer 10 upon curing. In the figures, the DVD master pattern has been modified in order to show both smaller pattern sections 22 and larger pattern sections 24, the significance of which will be discussed later with respect to the capillary wave effect. The master pattern can be supplied by any substrate that contains a geometry of pattern segments (such as those represented by valleys 13a and peaks 13b) that are to be imparted to the final patterned polymer film.

The master pattern 12 can be selected from virtually any substrate providing a geometry of pattern segments that can be imparted to an elastomer coated thereon. As will be described more particularly herein, the pattern segments may be chosen to either prevent or allow dewetting, as desired to create a specific pattern in the final patterned polymer film. By preventing dewetting in some segments and allowing dewetting in others, specific desired patterns can be obtained. The present invention advances the art by controlling dewetting by employing pattern segments that are smaller than the capillary wavelength of the polymer film that is to be patterned.

In one or more embodiments, the patterns in the mask are symmetrical. In other embodiments, the patterns are asymmetrical. The patterns can take any shape that is ultimately desired for the patterned polymer film.

Suitable master patterns 12 are generally known in the art and, by way of example, can be provided by conventional lithographic methods, such as those in the printed circuit industry. Suitable master patterns can be made in accordance with known methods.

In instances where the polymer film 16 will be annealed by a temperature-based annealing process, the curable elastomer 10 is chosen such that, once it is cured to form mask 14, the Tg of the mask 14 is higher than the Tg of the polymer film 16 to be patterned. This is important so that the mask 14 is not compromised during the temperature-based annealing of the polymer film 16. Similarly, in instances where the polymer film 16 will be annealed by a solvent-annealing process, the curable elastomer 10 is chosen such that, once it is cured to form mask 14, the cured elastomer of the mask 14 will not be compromised by the solvent employed to anneal the polymer film 16.

The curable elastomer may be chosen from virtually any curable elastomer, taking into account the concerns above regarding temperature-based and solvent-based annealing processes. By way of non-limiting example, siloxane, or any other elastomeric material that can be cast to the desired patterned shape may be employed. Non-limiting examples of suitable siloxanes include polydimethylsiloxanes, polydiphenylsiloxanes, and the family of silicones.

As used herein, a “curable elastomer” may be an elastomer having functional groups permitting a UV cure or may be a mixture of elastomer and curing agents (such as sulfur or peroxide) and, if desired, catalysts that accelerate the curing thereof to create the desired mask 14.

Curing agents and catalysts would be employed in common amounts and through common methods.

Suitably selected curable elastomers 10 are coated onto suitably selected master patterns 12 to fill the pattern thereof and are cured to create the desired mask 14, which is employed to confine a polymer film 16 on a substrate 18. After the cured mask is obtained, the mask is used to impart a pattern to a polymer film on a substrate. Thus, the provision of the polymer film on a substrate is next disclosed.

The substrate 18 may be chosen from virtually any material or product that benefits from being covered with a patterned polymer film.

Suitable substrates may be selected from glass, quartz, metal, and polymer substrates, all of which are typically used in the industry or research laboratories. The film on the substrate will be unstable owing to unfavorable long-range and short-range interactions, provided no substrate and/or polymer modification has been carried out that could alter these unfavorable interactions.

Polymer substrates can include homopolymers, polymer blends, and block copolymers.

Prior to coating the substrate 18 with the polymer film 16, the substrate 18 is appropriately cleaned so that no particulates interfere with the adherence of the polymer film 16 to the substrate 18. The cleaning procedures may include ultraviolet light exposure, acid treatment, base treatment, plasma treatment, treatment by solvent or blow-drying by inert gases.

In accordance with this invention, a polymer film 16 is coated onto the substrate 18 and confined by the mask 14. The polymer film 16 is annealed through a temperature-based or solvent-based annealing process, as already described above. After driving off solvent (in a solvent-annealing process) or quenching (in a temperature-based annealing process) the mask 14 is removed to leave behind a patterned polymer film 16 on a substrate 18. Dewetting is prevented by careful selection of the pattern on the mask 14. Particularly, dewetting is prevented at those pattern sections of the mask 14 that confine the polymer film 16 within dimensions less than the capillary wavelength of the polymer forming the polymer film 16.

The capillary wave effect occurs when a polymer film is heated. Similar to waves in the ocean, a polymer film will form waves when it is heated due to the capillary effect. A problem exists in the prior art when the troughs of the capillary waves are allowed to hit the substrate. If the troughs of the waves do hit the substrate, the polymer film will dewet and break into individual droplets. The troughs of the waves can hit the substrate because the capillary wave effect allows the waves to grow in magnitude if the waves are not disrupted.

By using a patterned elastomeric mask 14 having at least one pattern section that confines the polymer film 16 within dimensions less than the capillary wavelength of the polymer forming the polymer film 16, the capillary waves of the polymer film are disrupted at those pattern sections during the annealing step. As the capillary waves spread during annealing, they contact the walls 15 that define such a pattern section, and the walls 15 disrupt the capillary wave such that it cannot continue to grow and, most importantly, cannot cause the polymer to part at the surface of the substrate, which would lead to dewetting. It will be appreciated that the capillary wave necessarily includes a wavelength and amplitude. In one or more embodiments, the width (w, see FIG. 2) of a pattern section wherein dewetting is to be prevented is less than the capillary wavelength and the height (h, see FIG. 2) is larger than the amplitude of the capillary wave. In other embodiments, the height of pattern sections wherein dewetting is to be prevented is at least five times the radius of gyration of the polymer forming the polymer film, in other embodiments at least seven times the radius of gyration, and in other embodiments at least ten times the radius of gyration.

Thus, the walls 15 defining the pattern can be designed to correlate with the capillary wave properties of a given polymer film. The capillary wave properties depend on the molecular weight, annealing temperature, film thickness, and surface tension of the polymer film. Equations exist in the art to determine the capillary wavelength, and the capillary wavelength can also be determined experimentally. Thus, it is readily possible to design a desired mask 14 with appropriate pattern sections that disrupt the capillary wave. As seen in FIGS. 1-5, the mask 14 can be provided with both pattern sections such as those at pattern section 22, which are sized to disrupt the capillary wave of the polymer of the polymer film 16 and thus prevent dewetting during annealing, and pattern sections such as those at 24, which are sized larger than the capillary wave of the polymer forming the polymer film 16 and thus allow dewetting in those pattern sections. This dewetting typically occurs during the annealing step. Thus this invention provides means for controlling the dewetting of the polymer film 16 to create intricate patterned polymer films on substrates.

The polymer of the polymer film 16 can be chosen from virtually any suitable polymer, taking into account the concerns regarding degradation temperature (in a temperature-based annealing process) and solvents (in a solvent annealing process) as mentioned above. Suitable polymers include crystalline, semi-crystalline and amorphous polymers.

According to this invention, when a temperature-based annealing step is to be employed, any polymer that has a Tg below the degradation temperature of the elastomer of the mask 14 can be used to obtain a stable polymer film pattern. Again, this is necessary to prevent structurally compromising the mask 14 during a temperature-based annealing step, which brings the polymer film 16 above the Tg of the polymer thereof When a solvent-based annealing step is to be employed, any polymer that can be solvent annealed without compromising the mask 14 can be employed, i.e., the mask 14 should be stable in the presence of the solvent or solvents used to anneal.

For the polymer film to form patterns that are complete reproductions of the pattern section, the thickness of the film should be equal to or greater than the depth of the pattern features. However, at film thicknesses lower than pattern depth dimensions, film stability against dewetting is still achieved according to this invention and film thicknesses of less than the pattern depth may be desired in some embodiments.

The polymer film thickness should be increased with increasing horizontal periodicity of the pattern. For a pattern having a horizontal periodicity up to 1.7 μm, film thicknesses from 25 nm onwards can be stabilized and patterned. The completeness of the reproduction of the pattern depends on the depth of the pattern. When the film thickness is equal to or greater than the depth of the pattern, the film can form patterns that are complete reproductions of the pattern space. Thus, the invention holds true for any of the above mentioned conditions.

With reference to FIG. 3, the polymer film 16 is coated on the substrate 18. This may be achieved through any suitable process. Such processes include, but are not limited to spin coating, flow coating, floating pre-cast film on to substrate, sip coating and the like.

With further reference to FIG. 3, the elastomeric mask 14 is used to confine the polymer film 16 by covering the film with the mask 14 to confine it as disclosed herein. Notably, no external pressure is required, and the mask 14 can be applied under ambient conditions.

The assembly in FIG. 3 is then annealed, as represented in FIG. 4. One process of annealing is temperature-based. The temperature-based annealing step employs a vacuum oven at a temperature above the Tg of the confined polymer film. The temperature is maintained for a sufficient time period in order for the system to reach a metastable state.

The annealing causes the polymer film 16 to become more molten and rubber- like, and the polymer film 16 fills the pattern sections of the mask 14. In those pattern sections chosen to be smaller than the capillary wavelength, dewetting is prevented, and in those pattern sections chosen to be larger than the capillary wavelength, the polymer film 16 will dewet.

Another acceptable process of annealing uses a solvent to anneal the polymer film 16. In the solvent annealing process, the solvent is first vaporized. The solvent vapors then interact with the polymer film 16 to modify the molecular structure. This modification allows the polymer film 16 to fill the pattern sections of the mask 14.

After a temperature-based annealing step resulting in the conforming of the polymer film 16 to the pattern sections 22 and 24 (if present) of the mask 14 (see FIG. 4), the polymer film 16 is quenched by reducing the temperature below the Tg. This may be a simple as removing the sample from the oven to an atmosphere at a temperature below the Tg of the polymer film 16.

After annealing by solvent annealing, the solvent is driven off. This may be achieved (or accelerated) by placing the sample in an oven at a temperature much below the Tg of the polymer film 16 (so as not to compromise it).

As shown in FIG. 5, the mask 14 is then removed, leaving behind the patterned polymer film 16 on the substrate 18, with dewetting prevented in those areas where the dimensions of a pattern section were smaller than the capillary wavelength and with dewetting occurring in those areas (if any) where the dimensions of a pattern section were larger than the capillary wavelength.

The method of the present invention can be carried out in an industrialized, continuous process. That is, the method can be used for mass production of patterned polymer films by an assembly line. In this embodiment, as seen in FIG. 6, the elastomer mask is replaced with a roller wheel mask 26 that is marked with the protruding patterns 28 along the circumference of the roller wheel mask 26. A substrate 18 having a polymer film 30 coated thereon is advanced below the roller wheel mask 26, which rotates as the combination of substrate 18 and polymer film 30 passes thereunder. The protruding patterns 28 contact the polymer film 16 and confine it similar to the mask 14 as previously disclosed. As the roller wheel mask 26 rotates, the polymer film 30 is subsequently fed such that the protruding patterns 28 contact the polymer film 30. Heat from a heat source 32 would be provided underneath the polymer film 30 in order to achieve a temperature above the Tg while the polymer film 30 is in contact with the patterns 28 of the roller wheel 26. Alternatively, a solvent bath could be provided to solvent-anneal the polymer film 16. The polymer film 30 would be fed and the wheel mask 26 rotated at a sufficiently reduced speed such that the polymer film 30 would have sufficient time to anneal, substantially conforming to the pattern spaces 28, and ultimately forming the desired patterned polymer film 34. The patterns, film thickness, polymer film, method of annealing, and speed can all be designed in order to accomplish the goal of the present invention.

It will be appreciated that the coating of the polymer film on a substrate can be performed in a continuous process as known in the art, such that the substrate and polymer film combination can be advanced under the mask. Similarly, the mask, being in a roller wheel form allows for a continuous receipt and treatment of the combination substrate and polymer film. Indeed, it will be appreciated that the roller wheel type construct could be replaced by a conveyor belt type structure or other appropriate structure permitting continuous treatment of the polymer film. Thus, this invention generally provides a method for producing a patterned polymer film on a substrate, the method comprising the steps of: coating a substrate with a polymer film; advancing said substrate below a patterned object such that the polymer film contacts the patterned object, the patterned object having at least one pattern section of dimensions less than the capillary wavelength of the polymer film; while the polymer film is in contact with the patterned object, annealing the polymer film by a step selected from solvent annealing and temperature-based annealing, said step of annealing causing the polymer film to conform to the dimensions of the at least one pattern section of dimensions less than the capillary wavelength of the polymer film, thereby forming a patterned polymer film; and advancing the patterned polymer film such that the patterned object no longer contacts the patterned polymer film.

As is evident from the above description, the invention does not require expensive equipment, nor does it require tedious laboratory environmental conditions. A polymer film brought in contact with the elastomeric mask prepared by the method disclosed above is stabilized and patterned via simple temperature annealing. According to this invention, a polymer film can be stabilized and patterned simultaneously without having to handle toxic chemicals or nanoparticles. According to this invention, fewer steps are required, thus saving time and increasing the throughput of the outcome. The suggested method is reproducible and therefore large batches of the desired product can be consistently produced without significant changes in product quality.

Further, subsequent heating of the patterned stable films does not destroy their stability. Films thicker than the pattern depth size lose pattern features when re-heated above its Tg in the absence of any confinement. However, these films still retain stability against dewetting. Films thinner than the pattern depth dimensions retain stability as well as other film patterns, even when heated above the polymer Tg. The pattern depth serves as the cross-over thickness for the polymer films below which pattern and stability both are retained and above which only stability is retained on re-heating in the absence of confinement.

In light of the foregoing, it should be appreciated that the present invention significantly advances the art by providing a method of forming and stabilizing a patterned polymer film against dewetting where said method is structurally and functionally improved in a number of ways. While particular embodiments of the invention have been disclosed in detail herein, it should be appreciated that the invention is not limited thereto or thereby inasmuch as variations on the invention herein will be readily appreciated by those of ordinary skill in the art. The scope of the invention shall be appreciated from the claims that follow.

### EXAMPLES

### Creation of Mask:

In one example, Polydimethylsiloxane (PDMS), Sylgard 182 (Dow Corning) was used as the base elastomer for creation of the mask. A platinum catalyst in the Sylgard 182 kit was added to the elastomer in a ratio of 1:10 catalyst: elastomer and the mixture was degassed until all the air bubbles trapped in the elastomer were removed completely. It should be noted that the catalyst:elastomer ratio can be varied between 4:1 to 15:1 according to this invention. The resultant PDMS was then cast on a pre-cleaned master pattern.

The aluminum foil covering the patterned side of the digital versatile disc was peeled carefully and washed with methanol and water. The clean discs were then blow dried with nitrogen. The Degassed PDMS mixture was poured on the master pattern and cured at 120° C. for 2 hours. The above procedure was also tested at temperatures ranging from 20° C.-160° C. Similar results occurred at varying temperatures. However, the times required for complete curing varies with temperature. At 20° C.-60° C., the time required is 8-10 hours, at 60° C.-100° C. time required for complete curing is 6-8 hours, and for 100° C.-160° C. the time required for obtaining a completely cured PDMS mask is 2 hours. The cured mask was then allowed to cool for 15 minutes at room temperature and ambient conditions.

### Creation of Polymer Film on Substrate:

Polystyrene (PS) (Polymer Source Inc.) of molecular weight 4000 g/mol was dissolved in toluene at a concentration of 1 mass %, 2 mass %, and 3 mass %. These solutions were shaken in a vortex shaker for 24 hours and subsequently filtered through a 0.2 μm PTFE filter into clean glass vials.

Polymer films were prepared via spin coating polymer solutions at different spin speeds onto clean silicon wafers. Silicon wafers of size 2 inches×2 inches were cleaned by first washing with toluene, then blow drying with nitrogen and finally eliminating organic contaminants on the wafer by exposing them to ultra-violet ozone (UVO) for 1 hour. Film thicknesses ranging from 30 nm-250 nm were prepared. In this example, a 2 mass % PS solution was spin coated on silicon at a spin speed of 2000 rpm and an acceleration of 2000 rpm as well for a minute in order to obtain a thickness of 120 nm.

This invention holds true for substrate-cleaning procedures other than UVO exposure. Acid and/or base, plasma, and solvents can also be used for cleaning the substrates.

### Patterning of Polymer Film:

The polymer films were then confined by patterned PDMS stamps prepared by the method mentioned above. The confinement process did not involve any external pressure or clean-room conditions. The PDMS stamps were carefully placed on top of the polymer films.

The entire sample was then annealed in a vacuum oven at 140° C. for 24 hours.

The temperature chosen was above the Tg of PS (˜95° C.). The annealing temperature must be greater than the Tg of the polymer.

This invention holds true for PDMS cured at temperatures ranging from 20° C.-160° C. However, the times required for complete curing varies with temperature. At 20° C.-60° C., the time required is 8-10 hours, at 60° C.-100° C. time required for complete curing is 6-8 hours, and for 100° C.-160° C. the time required for obtaining a completely cured PDMS mask is 2 hours.

In order to test the robustness of the resultant stable and patterned films, they were annealed again at 140° C. for 24 hours. In this example, the film retained its stability against dewetting (as compared to an unconfined PS film annealed under similar conditions that would dewet silicon substrate instantaneously) but lost all pattern features. The goals of stabilizing and patterning the polymer film were thus achieved in this particular example.

After the annealing step, the assembly was quenched to a temperature below the Tg (˜80° C.).

In the end, the elastomeric mask of PDMS was carefully removed from the polymer film surface. The films were observed and characterized using an optical microscope and an atomic force microscope.

The patterned polymer film is completely stable as observed under an optical microscope and an atomic force microscope. No signs of film dewetting were observed throughout the film.

Various modifications and alterations that do not depart from the scope and spirit of this invention will become apparent to those skilled in the art. This invention is not to be duly limited to the illustrative embodiments set forth herein.

What is claimed is:

1. A method for producing a patterned polymer film on a substrate, the method comprising the steps of:
coating a substrate with a polymer film;
placing a patterned mask onto the surface of the polymer film, the patterned mask having at least one pattern section of dimensions less than the capillary wavelength of the polymer film;
annealing the polymer film by a step selected from solvent annealing and temperature-based annealing, which involves raising the temperature of the polymer film above its glass transition temperature, said step of annealing causing the polymer film to conform to the dimensions of the at least one pattern section of dimensions less than the capillary wavelength of the polymer film, thereby forming a patterned polymer film; and
removing the patterned mask from the patterned polymer film.

2. The method of claim 1, wherein the method further comprises the step of creating the patterned mask from a curable elastomer.

3. The method of claim 1, wherein the patterned polymer film is stabilized against dewetting.

4. The method of claim 1, wherein the step of annealing is a solvent annealing step and the method further comprises driving off the solvent after said step of annealing.

5. The method of claim 1, wherein the step of annealing is a temperature-based annealing step and the method further comprises quenching the polymer film after said step of annealing by reducing the temperature below the glass transition temperature.

6. The method of claim 1, wherein the mask has at least one pattern section of dimensions greater than the capillary wavelength of the polymer film.

7. A method for producing a patterned polymer film on a substrate, the method comprising the steps of:
coating a substrate with a polymer film;
advancing said substrate below a patterned object such that the polymer film contacts the patterned object, the patterned object having at least one pattern section of dimensions less than the capillary wavelength of the polymer film;
while the polymer film is in contact with the patterned object, annealing the polymer film by a step selected from solvent annealing and temperature-based annealing, said step of annealing causing the polymer film to conform to the dimensions of the at least one pattern section of dimensions less than the capillary wavelength of the polymer film, thereby forming a patterned polymer film; and
advancing the patterned polymer film such that the patterned object no longer contacts the patterned polymer film.

8. The method of claim 7, wherein the patterned object is rotating.

9. The method of claim 7, wherein the patterned object is a patterned roller wheel.

10. The method of claim 7, wherein the step of annealing is a temperature-based annealing step and the method further comprises quenching the polymer film after said step of annealing by reducing the temperature below the glass transition temperature.

11. The method of claim 7, wherein the step of annealing is a solvent annealing step and the method further comprises driving off the solvent after said step of annealing. 25

12. The method of claim 7, wherein the rate of advancement allows the polymer film to fully anneal while in contact with the patterned object.

13. The method of claim 7, wherein the patterned object has at least one pattern section of dimensions greater than the capillary wavelength of the polymer film.
